(19) United States
(12) Patent Application Publication
(10) Pub. No.: US 2023/0097307 A1
(43) Pub. Date: Mar. 30, 2023

(54) AIRFLOW BLOCKING DEVICE FOR USE IN SERVER RACKS

(71) Applicant: Microsoft Technology Licensing, LLC, Redmond, WA (US)

(72) Inventors: Kevin BUANA, Taoyuan City (TW); Anand Avinash KULKARNI, Redmond, WA (US)

(21) Appl. No.: 17/566,588

(22) Filed: Dec. 30, 2021

Related U.S. Application Data
(60) Provisional application No. 63/245,272, filed on Sep. 17, 2021.

(51) Int. Cl. H05K 7/14

(52) U.S. Cl. CPC H05K 7/1488

(57) ABSTRACT

A device for covering a portion of a server rack includes a main body having a front side, a back side, and a longitudinal axis, a locking element connected to a first longitudinal end of the main body, and an anchor element at a second longitudinal end of the main body. The anchor element is configured to engage with and slide longitudinally relative to the server rack.

### CROSS-REFERENCE TO RELATED APPLICATIONS

This application claims priority to and the benefit of U.S. Provisional Pat. Application No. 63/245,272, filed on Sep. 17, 2021, which is hereby incorporated by reference in its entirety.

### BACKGROUND

### Background and Relevant Art

There are millions of servers and hundreds of thousands of racks in data centers, leased sites, and private sites around the globe. Server racks have different levels of density constrained by different demands and datacenter capabilities. To improve the power efficiency of datacenters, server rack airflow blockers are a crucial part of rack infrastructure to prevent airflow mixing between the hot and cold aisles.

### BRIEF SUMMARY

In some embodiments, a device includes a main body, a locking element, and an anchor element. The main body includes a front side, a back side, a longitudinal axis, a first longitudinal end, and a second longitudinal end that is opposite the first longitudinal end. The main body is configured to cover a portion of a server rack. The locking element extends through the main body in a direction that is transverse to the longitudinal axis at the first longitudinal end. The locking element is configured to engage with a first aperture in the server rack. The anchor element is located at the second longitudinal end of the main body, and the anchor element is configured to engage with a second aperture in the server rack and to slide or rotate relative to the server rack.

In some embodiments, a method includes inserting a projection of an anchor element at a first end of an airflow blocking device into a first aperture of a server rack and locking the airflow blocking device in position by engaging a locking element with a second aperture of the server rack, the locking element being located at a second end of the airflow blocking device that is opposite the first end, the locking element extending through a main body of the airflow blocking device.

In some embodiments, a system includes a server rack and an airflow blocker. The server rack includes a first vertical support with a first aperture and a second vertical support with a second aperture. The airflow blocker includes a main body, a locking element, and an anchor element. The main body includes a front side, a back side, a longitudinal axis, a first longitudinal end, and a second longitudinal end that is opposite the first longitudinal end. The main body is configured to cover a portion of the server rack. The locking element extends through the main body in a direction that is transverse to the longitudinal axis at the first longitudinal end. The locking element is configured to engage with the first aperture in the server rack. The anchor element is located at the second longitudinal end of the main body, and the anchor element is configured to engage with the second aperture in the server rack and to slide or rotate relative to the server rack.

This Summary is provided to introduce a selection of concepts in a simplified form that are further described below in the Detailed Description. This Summary is not intended to identify key features or essential features of the claimed subject matter.

Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a front view of a server rack with a plurality of airflow blockers attached thereto, according to at least some embodiments of the present disclosure;

FIG. 2 is a rear perspective view of an airflow blocker, according to at least some embodiments of the present disclosure;

FIG. 3 is a rear detail view of an anchor element of the airflow blocker of FIG. 2, according to at least some embodiments of the present disclosure;

FIG. 4 is a top detail view of the anchor element of FIG. 3, according to at least some embodiments of the present disclosure;

FIG. 5 is a rear detail view of a locking element of the airflow blocker of FIG. 2, according to at least some embodiments of the present disclosure;

FIG. 6 is an end detail view of the locking element of FIG. 5 in an unlocked state, according to at least some embodiments of the present disclosure;

FIG. 7 is an end detail view of the locking element of FIG. 5 in a locked state, according to at least some embodiments of the present disclosure;

FIG. 8 is a rear perspective view of part of a server rack with a plurality of airflow blockers attached thereto, according to at least some embodiments of the present disclosure; and

FIG. 9 is an end cross-sectional view of the locking elements of the airflow blockers of FIG. 8, according to at least some embodiments of the present disclosure.

### DETAILED DESCRIPTION

The present disclosure generally relates to systems and methods for controlling airflow in a server rack. More particularly, the present disclosure relates to controlling airflow in a server rack by inhibiting or blocking airflow through a portion of the server rack. In some embodiments, the server rack has an opening in a front face thereof between server blades or other electronic components. Cool air is directed into the server rack to cool the server blades and/or electronic components. The opening can allow the cool air urged into the server rack to exit the server rack in an uncontrolled manner or direction, compromising the thermal management of the server blades and/or electronic components in the server rack.

A conventional server rack includes an airflow blocker positioned in the opening of the server rack that connects to the interior edge of the opening. The conventional airflow blocker accommodates the large manufacturing tolerances of the opening of the server rack with resilient clips that compress inward (e.g., toward a body of the airflow blocker) from the interior edges of the opening. Upon insertion, the resilient clips expand outward (e.g., away from the body of the airflow blocker) to retain the airflow blocker in the opening of the server rack. The clips engage with the interior edge to limit and/or prevent removal of the airflow blocker without an application of sufficient force. The opening of a conventional server rack has a manufacturing tolerance of approximately 2.6 millimeters (mm) to remain within acceptable specifications.

A conventional airflow blocker accommodates the manufacturing tolerance of the opening using plastics that, while flexible and resilient, are damaging to the environment both during manufacturing and post-lifecycle. More environmentally friendly materials, such as biodegradable plastics or recycled paper products, have lesser environmental impact during manufacturing and/or post-lifecycle, but may exhibit less desirable material properties for usage of the component. In at least one example, the range of motion of an elastic portion before transitioning to a plastic deformation or a brittle fracture of the material is less for a component manufactured from post-consumer recycled material than original manufactured plastics. A transition to plastic deformation regimes may cause the component to fail to restore to the original position or shape, and a brittle fracture may cause a clip or resilient member to break off entirely. In some cases, a broken clip may fall into other components of the server rack, causing further problems.

The present disclosure is directed to an airflow blocker that comprises a main body, a locking element connected to a first end of the main body, and an anchor element at a second end of the main body, as described herein. Some embodiments of a described airflow blocker provides coverage and/or closure of openings in a server rack to assist in controlling thermal management and climate control of the server rack and/or server room within a datacenter. In some embodiments, the airflow blocker provides greater versatility and more options for installation. For example, an airflow blocker according to the present disclosure allows for improved ease of installation and/or removal on a wider variety of server rack designs and with a wider variety of materials than a conventional airflow blocker. In at least one example, an airflow blocker according to the present disclosure may be manufacturer using a variety of materials and still accommodate tolerances in server rack construction. Because the described design of airflow blocker fits a wider tolerance of server rack openings, some embodiments of an airflow blocker can reduce both material waste in manufacturing and energy waste in thermal management due to poor fits on server racks.

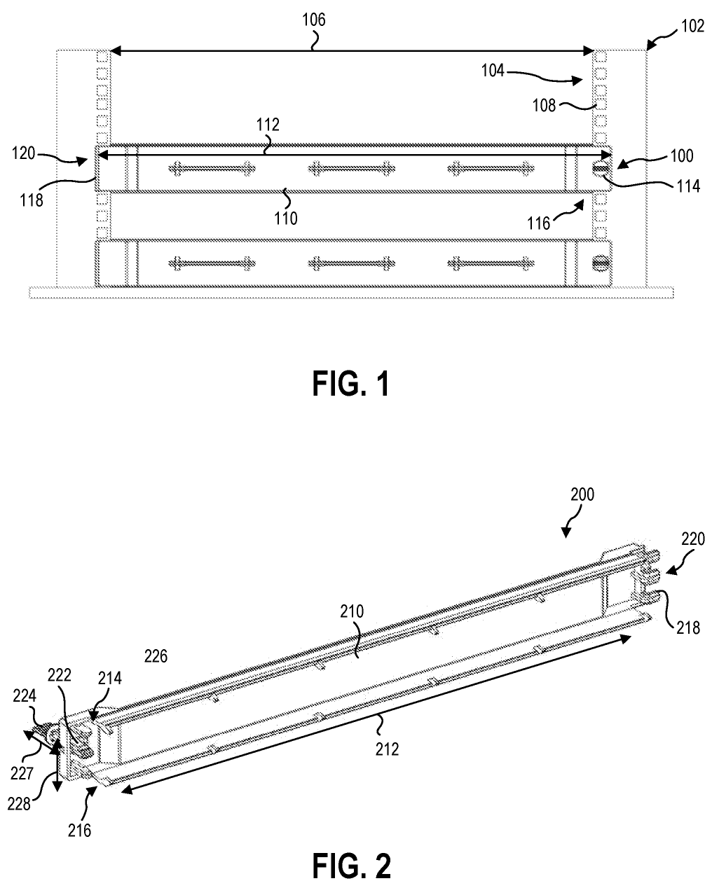

Referring now to FIG. 1, in some embodiments, an airflow blocker 100 according to the present disclosure securely retains its position in the server rack 102 while requiring less elastic deformation to accommodate the manufacturing tolerances of the server rack opening. A server rack 102 includes a plurality of vertical supports 104 that support server blades and other electronic devices positioned in the server rack 102. The opening 106 of the server rack 102 is defined by the space between the front vertical supports 104. The server rack 102 includes a series of apertures 108 in the front vertical supports 104 that allow server blades and other electronic devices to connect to and be supported by the vertical supports 104. The locations of the apertures 108 have the same manufacturing tolerances of the opening 106 of the server rack 102, and locations of the apertures 108 may vary in spacing by up to 2.6 mm while remaining withing acceptable specifications. Each aperture 108 of the plurality of apertures 108 has a manufacturing tolerance of 0.1 mm on the size of the aperture 108, however.

In some embodiments, an airflow blocker 100 has a main body 110 oriented in a longitudinal direction 112. The airflow blocker includes a locking element 114 at a first end 116 of the main body 110. At least a portion of the locking element 114 inserts into an aperture 108 of the server rack 102 and engages with the vertical support 104 to retain the first end 116 of the airflow blocker 100 relative to the aperture 108 and vertical support 104. In some embodiments, the airflow blocker 100 has an anchor element 118 positioned at a second end 120 of the main body 110 opposite the first end 116 in the longitudinal direction 112. The anchor element 118 includes one or more engagement members to engage with an aperture 108 in another vertical support 104. The anchor element 118 allows the airflow blocker 100 to slide or otherwise move relative to the server rack 102 in the longitudinal direction 112 of the airflow blocker 100 and across the opening of the server rack to accommodate the manufacturing tolerances of the server rack.

FIG. 2 is a rear perspective view of an embodiment of an airflow blocker 200. The airflow blocker 200 includes a locking element 214 at a first longitudinal end 216 of a main body 210 and an anchor element 218 at a second longitudinal end 220 of the main body 210 opposite the first longitudinal end 216 in the longitudinal direction 212. In some embodiments, the locking element 214 includes a clip 222 and a plunger 224. The plunger 224 inserts into the clip 222 in an insertion direction 227 to urge one or more arms 226 of the clip 222 to expand in a direction perpendicular to the insertion direction 227. In some embodiments, the arms 226 move in a transverse direction 228 perpendicular to the longitudinal direction 212 of the main body 210. In some embodiments, the arms 226 move in the longitudinal direction 212 of the main body 210. In other embodiments, the locking element 214 engages with the aperture(s) of the vertical support in other manners, such as with a mechanical fastener including a catch, clip, pin, threaded rod, screw, bolt, nut; with a press fit; with a friction fit; with a magnetic force; or with another connection mechanism. For example, the locking element 214 may include a rod that inserts into the aperture to vertically support the airflow blocker relative to the vertical support, while a magnet in the locking element 214 generates a magnetic attractive force between the locking element and the vertical support.

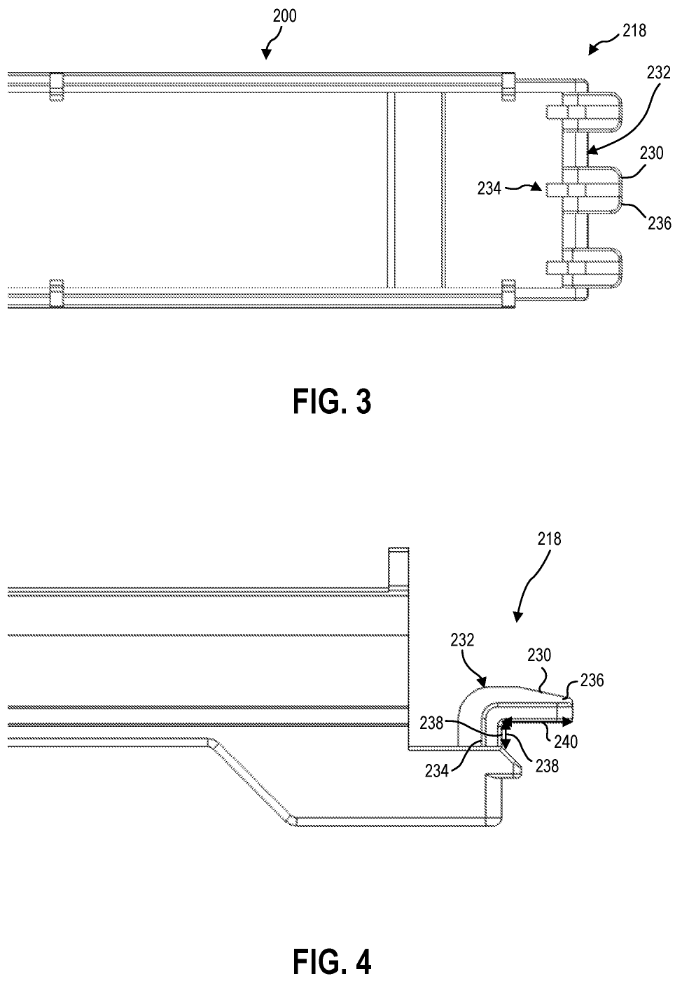

Referring now to FIG. 3, the anchor element 218 includes one or more projections 230 that allow the airflow blocker 200 to engage with one or more apertures of the server rack. In some embodiments, the projections 230 include a curve or a corner 232. The curve or corner 232 in the projection(s) 230 allow the anchor element 218 to function similar to a hinge when the projection(s) 230 is inserted into the aperture(s) of the vertical support of the server rack. For example, to install the airflow blocker 200, the anchor element 218 of the airflow blocker 200 may be inserted into the aperture(s) of the vertical support and the airflow blocker 200 may be rotated relative to the vertical support around the curve or corner 232 in the anchor element 218 to move the locking element (such as the locking element 214 of FIG. 2) toward the second vertical support.

In some embodiments, a projection 230 of the anchor element 218 includes a post 234 and a foot 236. The post 234 extends in a transverse direction relative to the longitudinal direction of the main body, and the foot 236 is oriented at an angle to the post 234 and projects at least partially in the longitudinal direction or a direction substantially parallel to the longitudinal direction. In some embodiments, the foot 236 extends at least 5 mm in the longitudinal direction. In some embodiments, the post 234 and foot 236 meet at a corner 232, such as illustrated in FIG. 4. In some embodiments, the post transitions to the foot in a curve.

The post 234 may have a height 238 in the transverse direction in a range having an upper value, a lower value, or upper and lower values including any of 1 mm, 2 mm, 3 mm, 4 mm, 5 mm, 6 mm, 7 mm, 8 mm, 9 mm, 10 mm, or any values therebetween. For example, the post 234 may have a height 238 that is greater than 1 mm. In some examples, the post 234 has a height 238 less than 10 mm. In some examples, the post 234 has a height 238 between 1 mm and 10 mm. In some examples, the post 234 has a height 238 between 2.5 mm and 7.5 mm. In at least one example, the post 234 has a height 238 of approximately 5 mm. For example, a post with a height of approximately 5 mm may allow clearance for rotation of the airflow blocker around the projection as a hinge.

The foot 236 may have a length 240 in the longitudinal direction in a range having an upper value, a lower value, or upper and lower values including any of 1 mm, 2 mm, 3 mm, 4 mm, 5 mm, 6 mm, 7 mm, 8 mm, 9 mm, 10 mm, 12 mm, 14 mm, 16 mm, 18 mm, 20 mm, or any values therebetween. For example, the foot 236 may have a length 240 that is greater than 1 mm. In some examples, the foot 236 has a length 240 of less than 20 mm. In some examples, the foot 236 has a length 240 between 1 mm and 20 mm. In some examples, the foot 236 has a length 240 between 5 mm and 15 mm. In at least one example, the foot 236 has a length 240 of approximately 10 mm. For example, a foot with a length of approximately 10 mm allows the airflow blocker to accommodate tolerances of the server rack opening without disconnecting from the aperture of the server rack.

In some embodiments, at least one projection of the anchor element 214 is substantially straight. For example, the projection may be substantially straight and oriented at an angle to the main body and/or the longitudinal direction of the main body. In a specific example, the projection is oriented at a 30° angle to the longitudinal direction such that a distal end of the projection is approximately 10 mm in the longitudinal direction and 5 mm in the transverse direction from a point at which the projection is connected to the main body.

While some embodiments of an airflow blocker described herein include a locking element at a first end of the main body and an anchor element at an opposite second end, in at least one embodiment, an airflow blocker includes a first locking element at a first end of the main body and a second locking element at an opposite second end.

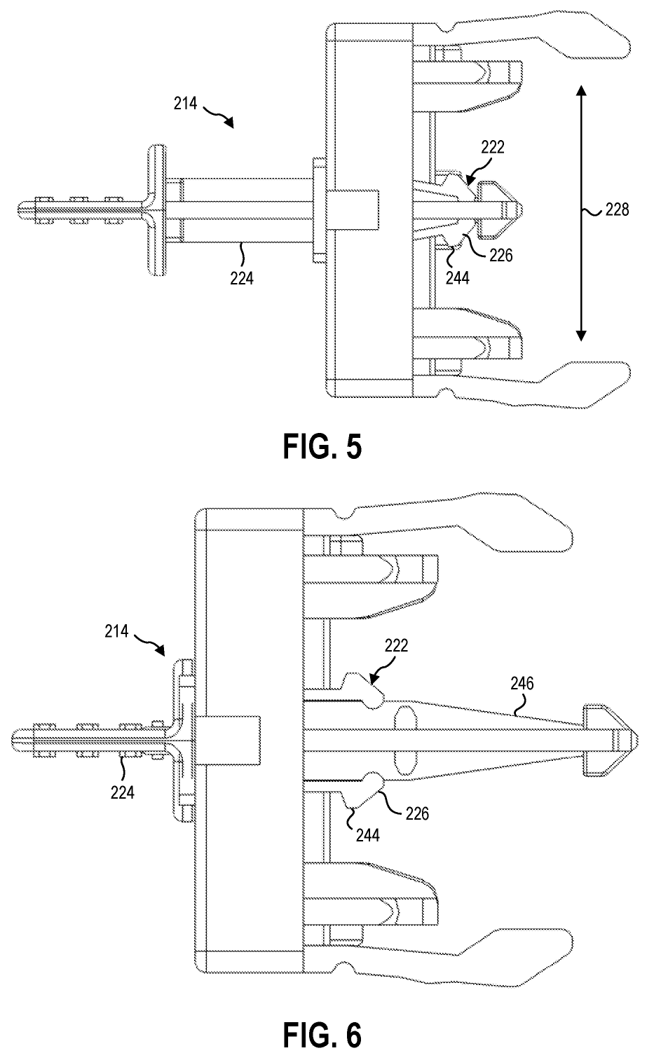

FIG. 5 is an end view of an airflow blocker and locking element in an unlocked state. The locking element 214 includes a clip 222 with elastically deformable arms 226. The elastically deformable arms 226 are biased toward a closed state. In some embodiments, such as that illustrated in FIG. 6, when the arms 226 are in the closed state, the locking element 214 is in the unlocked state. In other embodiments, the locking element may be in a locked state when the arms are in a closed state. In some embodiments, the clip 222 has a plurality of arms 226, such as illustrated in FIG. 5. In some embodiments, a clip 222 has only one arm 226.

In some embodiments, one or more arms 226 include a shoulder 244 or other engagement feature that engages with the vertical support of the server rack when in the locked state. For example, when the clip 222 is in the closed state, the shoulder 244 of the arms 226 may pass through the aperture in the vertical support. The clip 222 and locking element 214 may, therefore, be inserted into the vertical support. While the locking element 214 is in the unlocked state and the clip 222 is in the closed state, the locking element 214 may subsequently be removed through the aperture, as well. When the locking element 214 is moved to the locked state and the clip 222 is in the open state, the shoulders 244 or other engagement features of the clip 222 and/or locking element 214 engage with the vertical support around the aperture to limit and/or prevent removal of the locking element 214 from the aperture.

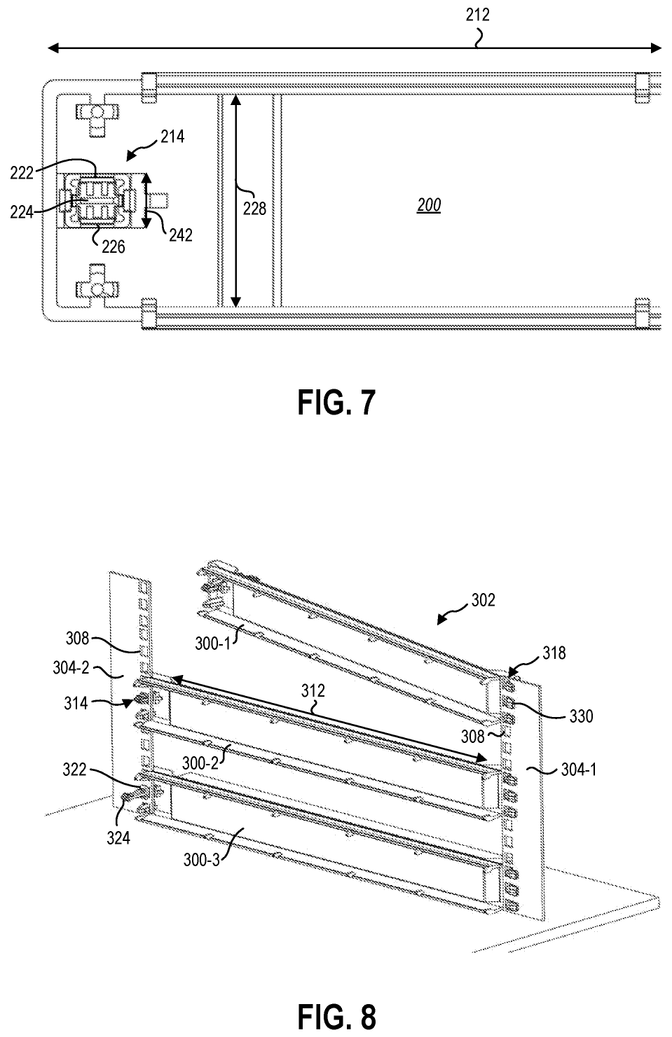

FIG. 6 is an end view of the airflow blocker and locking element of FIG. 5 in a locked state. In some embodiments, the arms 226 of the clip 222 are expanded by inserting a plunger 224 between and/or against the arms 226 of the clip 222. The plunger 224 may have a tapered outer surface 246 that expands the arm(s). During insertion of the plunger 224 from the retracted position, such as illustrated in FIG. 6, to the inserted position, such as illustrated in FIG. 7, the outer surface 246 of the plunger 224 applies an outward force to the arm(s) 226 to move the arm(s) 226 from the closed position to the open position. When the arms 226 are in the open position, the shoulder 244 or other engagement feature may contact the vertical support, securing the airflow blocker in place.

The insertion of the plunger 224 elastically deforms the arm(s) 226 toward the open position, such that removal of plunger 224 (e.g., retracting the plunger toward the retracted position illustrated in FIG. 5) allows that arm(s) 226 to elastically restore to closed state. In contrast to a conventional airflow blocker, the range of motion through which the arm(s) 226 move is smaller, allowing a greater range of materials with a lower modulus of elasticity and/or lower yield strength.

In some embodiments, the tip of the arm 226 in a locking element 214 displaces less than 5 mm between the closed state and the open state. In other embodiments, the tip of the arm 226 in a locking element 214 displaces less than 4 mm between the closed state and the open state. In yet other embodiments, the tip of the arm 226 in a locking element 214 displaces less than 2.5 mm between the closed state and the open state.

In some embodiments, the arm 226 in a locking element 214 rotates less than 20° between the closed state and the open state. In other embodiments, the arm 226 in a locking element 214 rotates less than 10° between the closed state and the open state. In yet other embodiments, the arm 226 in a locking element 214 rotates less than 5° between the closed state and the open state.

FIG. 7 is a rear view of an embodiment of an end of an airflow blocker that includes a locking element 214. The locking element 214 includes a selectively lockable mechanism that is movable from an unlocked state to a locked state and back. In some embodiments, the locking element 214 includes an elastically deformable clip 222 that is insertable through an aperture of the vertical support. The elastically deformable clip 222 engages with the vertical support to retain the locking element 214 in the aperture and secure the airflow blocker 200 to the vertical support. In some embodiments, the elastically deformable clip 222 includes at least one arm 226 that moves perpendicular to an insertion direction (such as insertion direction 227 of FIG. 2) of the plunger 224. In some embodiments, the elastically deformable clip 222 includes at least one arm 226 that moves in the transverse direction 228 when moved from the unlocked state to the locked state. In some embodiments, the elastically deformable clip 222 includes at least one arm that moves in the longitudinal direction 212 when moved from the unlocked state to the locked state. In some embodiments, the elastically deformable clip 222 includes at least one arm that moves in the longitudinal direction 212 when moved from the unlocked state to the locked state and at least one arm that moves in the transverse direction 228 when moved from the unlocked state to the locked state.

The elastically deformable clip 222 and/or arm(s) 226 define a width 242 of the locking element 214. In the illustrated embodiment in FIG. 7, the width 242 relative to the transverse direction 228 changes as the arm(s) 226 move relative to the transverse direction 228. In some embodiments, the locking element 214 has a width 242 that is less than 10 mm in the unlocked state. The width 242 increases as the locking element 214 moves from the unlocked state to the locked state. For example, a difference in width 242 between the unlocked state and the locked state may be less than 10 mm. In other examples, the difference in width 242 between the unlocked state and the locked state may be less than 5 mm. In yet other examples, the difference in width 242 between the unlocked state and the locked state may be less than 2 mm. In some embodiments, an airflow blocker 200 that engages with a support and locks in place with a relatively small difference in width 242 (e.g., expansion of the arms 226) allows for a wider variety of materials to be used in manufacturing of the airflow blocker 200 and/or the elastically deformable clip 222.

FIG. 8 is a perspective view of a pair of vertical supports 304-1, 304-2 with embodiments of an airflow blocker 300-1, 300-2, 300-3 illustrating the stages of connecting the airflow blockers 300-1, 300-2, 300-3 to a server rack 302. In some embodiments, attaching an airflow blocker according to the present disclosure to a server rack includes inserting an anchor element 318 of the airflow blocker into a first vertical support 304-1. The anchor element 318 may include one or more projections 330 that enter apertures 308 in the first vertical support 304-1.

The first airflow blocker 300-1 of FIG. 8 is connected to the first vertical support 304-1 by the anchor element 318. The second airflow blocker 300-2 shows the system after rotating around the connection between the anchor element 318 and the first vertical support 304-1 to insert the locking element 314 into an aperture 308 of the second vertical support 304-2. In some embodiments, the anchor element 318 slides in a longitudinal direction 312 relative to the first vertical support 304-1 while remaining engaged with the first vertical support 304-1 by up to 10 mm to accommodate manufacturing tolerances in the server rack 302. In some embodiments, the anchor element 318 slides in a longitudinal direction 312 relative to the first vertical support 304-1 while remaining engaged with the first vertical support 304-1 by up to 5 mm to accommodate manufacturing tolerances in the server rack 302. In some embodiments, the anchor element 318 slides in a longitudinal direction 312 relative to the first vertical support 304-1 while remaining engaged with the first vertical support 304-1 by up to 2.6 mm to accommodate manufacturing tolerances in the server rack 302.

The second airflow blocker 300-2 shows the locking element 314 in the unlocked state to allow the locking element 314 to enter the aperture 308 of the second vertical support 304-2. The third airflow blocker 300-3 shows a plunger 324 inserted into the clip 322 of the locking element 314 to expand the clip 322 and move the locking element 314 to the locked state. In some embodiments, the plunger 324 ensures the locking element 314 remains in the locked state, until a technician retracts the plunger 324, reversing the process.

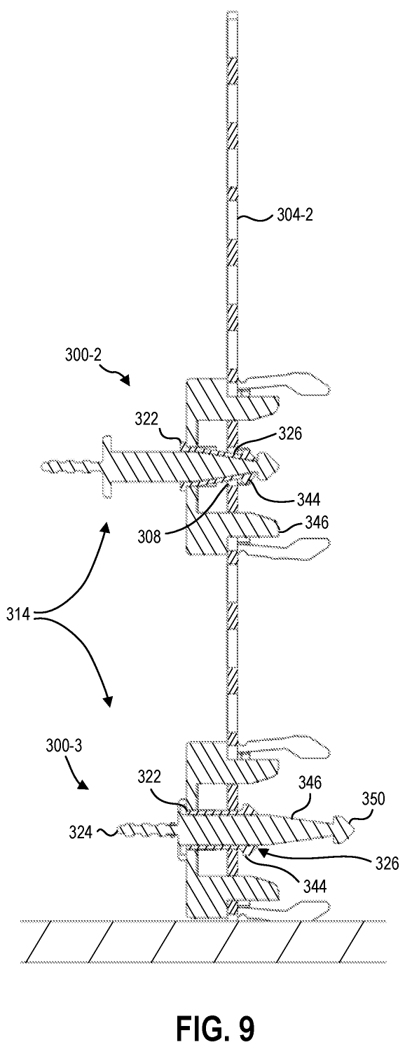

FIG. 9 is a cross-sectional end view of the locking elements 314 of the second airflow blocker 300-2 and the third airflow blocker 300-3 of FIG. 8. The locking element 314 of the second airflow blocker 300-2 is in an unlocked state with the clip 322 in a closed state. The arms 326 of the clip 322 are biased inward toward the closed state, and the shoulders 344 of the arms 326 have a width small enough to allow insertion into the aperture 308.

The third airflow blocker 300-3 has the plunger 324 in an inserted state. The tapered outer surface 346 of the plunger 324 urges the arms 326 of the clip 322 outward toward an open state, as the plunger 324 is inserted. The arms 326 (and shoulders 344) of the clip 322 are moved outward, increasing the width of the clip 322. The shoulders 344 then limit and/or prevent the removal of the locking element 314 when the locking element 314 is in the locked state. To remove the airflow blocker, the plunger is retracted and returned to the retracted state of the second airflow blocker. Because the arms of the clip are biased toward the closed state, the arms elastically restore to the closed state, such that the arms and shoulders have a width less than the aperture, as shown by the second airflow blocker. In some embodiments, a retention tip 350 on the plunger 324 is larger than a gap between the arms 326 in the closed state, and the retention tip 350 limits and/or prevents retracting the plunger 324 beyond the retracted state. The plunger 324, therefore, is not fully removed, allowing the plunger 324 to be retained by the locking element 314 to re-lock the locking element 314 when needed.

### INDUSTRIAL APPLICABILITY

The present disclosure generally relates to systems and methods for controlling airflow in a datacenter. A conventional airflow blocker accommodates the manufacturing tolerance of the opening using plastics that, while flexible and resilient, are damaging to the environment both during manufacturing and post-lifecycle. More environmentally friendly materials, such as biodegradable plastics or recycled paper products, have lesser environmental impact during manufacturing and/or post-lifecycle, but may exhibit less desirable material properties for usage of the component. In at least one example, the range of motion of an elastic portion before transitioning to a plastic deformation or a brittle fracture of the material is less for a component manufactured from post-consumer recycled material than original manufactured plastics. A transition to plastic deformation regimes may cause the component to fail to restore to the original position or shape, and a brittle fracture may cause a clip or resilient member to break off entirely. In some cases, a broken clip may fall into other components of the server rack, causing further problems.

In some embodiments, an airflow blocker according to the present disclosure securely retains its position in the server rack while requiring a smaller elastic deformation to accommodate the manufacturing tolerances of the server rack opening. In some embodiments, a server rack includes a plurality of vertical supports that support server blades and other electronic devices positioned in the server rack. The opening of the server rack is defined by the space between the front vertical supports. The server rack includes a series of apertures in the front vertical supports that allow server blades and other electronic devices to connect to and be supported by the vertical supports. The locations of the apertures have the same manufacturing tolerances of the opening of the server rack, and locations of the apertures may vary in spacing by up to 2.6 mm while remaining withing acceptable specifications. Each aperture of the plurality of apertures has a manufacturing tolerance of 0.1 mm.

The present disclosure is directed to an airflow blocker that comprises a main body, a locking element connected to a first end of the main body, and an anchor element at a second end of the main body, as described herein. Some embodiments of a described airflow blocker provides coverage and/or closure of openings in a server rack to assist in controlling thermal management and climate control of the server rack and/or server room within a datacenter. In some embodiments, the airflow blocker provides greater versatility and more options for installation. For example, an airflow blocker according to the present disclosure allows for improved ease of installation and/or removal on a wider variety of server rack designs and with a wider variety of materials than a conventional airflow blocker. In at least one example, an airflow blocker according to the present disclosure may be manufacturer using a variety of materials and still accommodate tolerances in server rack construction. Because the described design of airflow blocker fits a wider tolerance of server rack openings, some embodiments of an airflow blocker can reduce both material waste in manufacturing and energy waste in thermal management due to poor fits on server racks.

In some embodiments, an airflow blocker according to the present disclosure securely retains its position in the server rack while requiring less elastic deformation to accommodate the manufacturing tolerances of the server rack opening. A server rack includes a plurality of vertical supports that support server blades and other electronic devices positioned in the server rack. The opening of the server rack is defined by the space between the front vertical supports. The server rack includes a series of apertures in the front vertical supports that allow server blades and other electronic devices to connect to and be supported by the vertical supports. The locations of the apertures have the same manufacturing tolerances of the opening of the server rack, and locations of the apertures may vary in spacing by up to 2.6 mm while remaining withing acceptable specifications. Each aperture of the plurality of apertures has a manufacturing tolerance of 0.1 mm on the size of the aperture, however.

In some embodiments, an airflow blocker has a main body oriented in a longitudinal direction. The airflow blocker includes a locking element at a first end of the main body. At least a portion of the locking element inserts into an aperture of the server rack and engages with the vertical support to retain the first end of the airflow blocker relative to the aperture and vertical support. In some embodiments, the airflow blocker has an anchor element positioned at a second end of the main body opposite the first end in the longitudinal direction. The anchor element includes one or more engagement members to engage with an aperture in another vertical support. The anchor element allows the airflow blocker to slide or otherwise move relative to the server rack in the longitudinal direction of the airflow blocker and across the opening of the server rack to accommodate the manufacturing tolerances of the server rack.

In some embodiments, the airflow blocker includes a locking element at a first longitudinal end of a main body and an anchor element at a second longitudinal end of the main body opposite the first longitudinal end in the longitudinal direction. In some embodiments, the locking element includes a clip and a plunger. The plunger inserts into the clip in an insertion direction to urge one or more arms of the clip to expand in a direction perpendicular to the insertion direction. In some embodiments, the arms move in a transverse direction perpendicular to the longitudinal direction of the main body. In some embodiments, the arms move in the longitudinal direction of the main body. In other embodiments, the locking element engages with the aperture(s) of the vertical support in other manners, such as with a mechanical fastener including a catch, clip, pin, threaded rod, screw, bolt, nut; with a press fit; with a friction fit; with a magnetic force; or with another connection mechanism. For example, the locking element may include a rod that inserts into the aperture to vertically support the airflow blocker relative to the vertical support, while a magnet in the locking element generates a magnetic attractive force between the locking element and the vertical support.

In some embodiment, the anchor element includes one or more projections that allow the airflow blocker to engage with one or more apertures of the server rack. In some embodiments, the projections include a curve or a corner. The curve or corner in the projection(s) allow the anchor element to function similar to a hinge when the projection(s) is inserted into the aperture(s) of the vertical support of the server rack. For example, to install the airflow blocker, the anchor element of the airflow blocker may be inserted into the aperture(s) of the vertical support and the airflow blocker may be rotated relative to the vertical support around the curve or corner in the anchor element to move the locking element toward the second vertical support.

In some embodiments, a projection of the anchor element includes a post and a foot. The post extends in a transverse direction relative to the longitudinal direction of the main body, and the foot is oriented at an angle to the post and projects at least partially in the longitudinal direction or a direction substantially parallel to the longitudinal direction. In some embodiments, the foot extends at least 5 mm in the longitudinal direction. In some embodiments, the post and foot meet at a corner. In some embodiments, the post transitions to the foot in a curve.

The post may have a height in the transverse direction in a range having an upper value, a lower value, or upper and lower values including any of 1 mm, 2 mm, 3 mm, 4 mm, 5 mm, 6 mm, 7 mm, 8 mm, 9 mm, 10 mm, or any values therebetween. For example, the post may have a height that is greater than 1 mm. In some examples, the post has a height less than 10 mm. In some examples, the post has a height between 1 mm and 10 mm. In some examples, the post has a height between 2.5 mm and 7.5 mm. In at least one example, the post has a height of approximately 5 mm. For example, a post with a height of approximately 5 mm may allow clearance for rotation of the airflow blocker around the projection as a hinge.

The foot may have a length in the longitudinal direction in a range having an upper value, a lower value, or upper and lower values including any of 1 mm, 2 mm, 3 mm, 4 mm, 5 mm, 6 mm, 7 mm, 8 mm, 9 mm, 10 mm, 12 mm, 14 mm, 16 mm, 18 mm, 20 mm, or any values therebetween. For example, the foot may have a length that is greater than 1 mm. In some examples, the foot has a length of less than 20 mm. In some examples, the foot has a length 240 between 1 mm and 20 mm. In some examples, the foot has a length 240 between 5 mm and 15 mm. In at least one example, the foot has a length of approximately 10 mm. For example, a foot with a length of approximately 10 mm allows the airflow blocker to accommodate tolerances of the server rack opening without disconnecting from the aperture of the server rack.

In some embodiments, at least one projection of the anchor element is substantially straight. For example, the projection may be substantially straight and oriented at an angle to the main body and/or the longitudinal direction of the main body. In a specific example, the projection is oriented at a 30° angle to the longitudinal direction such that a distal end of the projection is approximately 10 mm in the longitudinal direction and 5 mm in the transverse direction from a point at which the projection is connected to the main body.

While some embodiments of an airflow blocker described herein include a locking element at a first end of the main body and an anchor element at an opposite second end, in at least one embodiment, an airflow blocker includes a first locking element at a first end of the main body and a second locking element at an opposite second end.

In some embodiments, a locking element includes a clip with elastically deformable arms. The elastically deformable arms are biased toward a closed state. In some embodiments, when the arms are in the closed state, the locking element is in the unlocked state. In other embodiments, the locking element may be in a locked state when the arms are in a closed state. In some embodiments, the clip has a plurality of arms. In some embodiments, a clip has only one arm.

In some embodiments, one or more arms include a shoulder or other engagement feature that engages with the vertical support of the server rack when in the locked state. For example, when the clip is in the closed state, the shoulder of the arms may pass through the aperture in the vertical support. The clip and locking element may, therefore, be inserted into the vertical support. While the locking element is in the unlocked state and the clip is in the closed state, the locking element may subsequently be removed through the aperture, as well. When the locking element is moved to the locked state and the clip is in the open state, the shoulders or other engagement features of the clip and/or locking element engage with the vertical support around the aperture to limit and/or prevent removal of the locking element from the aperture.

In some embodiments, the arms of the clip are expanded by inserting a plunger between and/or against the arms of the clip. The plunger may have a tapered outer surface that expands the arm(s). During insertion of the plunger from the retracted position to the inserted position, the outer surface of the plunger applies an outward force to the arm(s) to move the arm(s) from the closed position to the open position. When the arms are in the open position, the shoulder or other engagement feature may contact the vertical support, securing the airflow blocker in place.

The insertion of the plunger elastically deforms the arm(s) toward the open position, such that removal of plunger (e.g., retracting the plunger toward the retracted position) allows that arm(s) to elastically restore to closed state. In contrast to a conventional airflow blocker, the range of motion through which the arm(s) move is smaller, allowing a greater range of materials with a lower modulus of elasticity and/or lower yield strength.

In some embodiments, the tip of the arm in a locking element displaces less than 5 mm between the closed state and the open state. In other embodiments, the tip of the arm in a locking element displaces less than 4 mm between the closed state and the open state. In yet other embodiments, the tip of the arm in a locking element displaces less than 2.5 mm between the closed state and the open state.

In some embodiments, the arm in a locking element rotates less than 20° between the closed state and the open state. In other embodiments, the arm in a locking element rotates less than 10° between the closed state and the open state. In yet other embodiments, the arm in a locking element rotates less than 5° between the closed state and the open state.

The locking element includes a selectively lockable mechanism that is movable from an unlocked state to a locked state and back. In some embodiments, the locking element includes an elastically deformable clip that is insertable through an aperture of the vertical support. The elastically deformable clip engages with the vertical support to retain the locking element in the aperture and secure the airflow blocker to the vertical support. In some embodiments, the elastically deformable clip includes at least one arm that moves perpendicular to an insertion direction of the plunger. In some embodiments, the elastically deformable clip includes at least one arm that moves in the transverse direction when moved from the unlocked state to the locked state. In some embodiments, the elastically deformable clip includes at least one arm that moves in the longitudinal direction when moved from the unlocked state to the locked state. In some embodiments, the elastically deformable clip includes at least one arm that moves in the longitudinal direction when moved from the unlocked state to the locked state and at least one arm that moves in the transverse direction when moved from the unlocked state to the locked state.

The elastically deformable clip and/or arm(s) define a width of the locking element. In some embodiments, the width relative to the transverse direction changes as the arm(s) move relative to the transverse direction. In some embodiments, the locking element has a width that is less than 10 mm in the unlocked state. The width increases as the locking element moves from the unlocked state to the locked state. For example, a difference in width between the unlocked state and the locked state may be less than 10 mm. In other examples, the difference in width between the unlocked state and the locked state may be less than 5 mm. In yet other examples, the difference in width between the unlocked state and the locked state may be less than 2 mm. In some embodiments, an airflow blocker that engages with a support and locks in place with a relatively small difference in width (e.g., expansion of the arms) allows for a wider variety of materials to be used in manufacturing of the airflow blocker and/or the elastically deformable clip.

In some embodiments, attaching an airflow blocker according to the present disclosure to a server rack includes inserting an anchor element of the airflow blocker into a first vertical support. The anchor element may include one or more projections that enter apertures in the first vertical support.

In some embodiments, the anchor element slides in a longitudinal direction relative to the first vertical support while remaining engaged with the first vertical support by up to 10 mm to accommodate manufacturing tolerances in the server rack. In some embodiments, the anchor element slides in a longitudinal direction relative to the first vertical support while remaining engaged with the first vertical support by up to 5 mm to accommodate manufacturing tolerances in the server rack. In some embodiments, the anchor element slides in a longitudinal direction relative to the first vertical support while remaining engaged with the first vertical support by up to 2.6 mm to accommodate manufacturing tolerances in the server rack.

In some embodiments, a plunger inserted into the clip of the locking element expands the clip and moves the locking element to the locked state. In some embodiments, the plunger ensures the locking element remains in the locked state, until a technician retracts the plunger, reversing the process.

In some embodiments, the locking element of the airflow blocker is in an unlocked state with the clip in a closed state. The arms of the clip are biased inward toward the closed state, and the shoulders of the arms have a width small enough to allow insertion into the aperture.

In some embodiments, a tapered outer surface of the plunger urges the arms of the clip outward toward an open state, as the plunger is inserted. The arms (and shoulders) of the clip are moved outward, increasing the width of the clip. The shoulders then limit and/or prevent the removal of the locking element when the locking element is in the locked state. To remove the airflow blocker, the plunger is retracted and returned to the retracted state of the second airflow blocker. Because the arms of the clip are biased toward the closed state, the arms elastically restore to the closed state, such that the arms and shoulders have a width less than the aperture, as shown by the second airflow blocker. In some embodiments, a retention tip on the plunger is larger than a gap between the arms in the closed state, and the retention tip limits and/or prevents retracting the plunger beyond the retracted state. The plunger, therefore, is not fully removed, allowing the plunger to be retained by the locking element to re-lock the locking element when needed.

Embodiments of systems and methods for restricting and/or controlling airflow in a server rack are described herein according to at least some of the following sections:

[A1] In some embodiments, a device includes a main body, a locking element, and an anchor element. The main body includes a front side, a back side, a longitudinal axis, a first longitudinal end, and a second longitudinal end that is opposite the first longitudinal end. The main body is configured to cover a portion of a server rack. The locking element extends through the main body in a direction that is transverse to the longitudinal axis at the first longitudinal end. The locking element is configured to engage with a first aperture in the server rack. The anchor element is located at the second longitudinal end of the main body, and the anchor element is configured to engage with a second aperture in the server rack and to slide or rotate relative to the server rack.

[A2] In some embodiments, the anchor element of [A1] includes a projection protruding from the main body at least partially in a direction that is substantially parallel to the longitudinal axis.

[A3] In some embodiments, the projection of [A2] has a port with a height no more than 10 mm.

[A4] In some embodiments, the projection of [A2] or [A3] has a foot with a length no more than 20 mm.

[A5] In some embodiments, the locking element of any of [A1] through [A4] has a locked state and an unlocked state, and the locking element has a first width in the locked state and a second width that is less than the first width in the unlocked state.

[A6] In some embodiments, the unlocked state of [A5] has a width no more than 10 mm.

[A7] In some embodiments, the locked state and unlocked state of [A5] or [A6] has a difference in width of no more than 5 mm.

[A8] In some embodiments, the locking element of any of [A1] through [A7] projects in a transverse axis that is substantially perpendicular to the longitudinal axis, and the locking element comprises an arm that is elastically movable.

[A9] In some embodiments, the locking element of any of [A1] through [A8] includes an elastically deformable clip and a plunger.

[A10] In some embodiments, the elastically deformable clip of [A9] has an arm that is movable in a direction that is substantially perpendicular to an insertion direction of the plunger.

[A11] In some embodiments, the elastically deformable clip of [A9] includes an arm, and the plunger of [A9] includes a tapered outer surface that contacts and applies a force to the arm.

[A12] In some embodiments, the elastically deformable clip of [A9] includes a plurality of arms, and the plunger of [A9] includes a tapered outer surface that contacts and applies a force to the plurality of arms.

[A13] In some embodiments, the elastically deformable clip of any of [A9] through [A12] has an arm that is movable in a transverse direction that is substantially perpendicular to the longitudinal axis.

[A14] In some embodiments, the elastically deformable clip of any of [A9] through [A12] has an arm that is movable in a direction that is substantially parallel to the longitudinal axis.

[B1] In some embodiments, a method includes inserting a projection of an anchor element at a first end of an airflow blocking device into a first aperture of a server rack and locking the airflow blocking device in position by engaging a locking element with a second aperture of the server rack, the locking element being located at a second end of the airflow blocking device that is opposite the first end, the locking element extending through a main body of the airflow blocking device.

[B2] In some embodiments, the locking element of [B1] includes an elastically deformable clip and a plunger, and the locking the airflow blocking device in position including sliding the plunger through the main body such that it applies a force to an arm of the elastically deformable clip.

[C1] In some embodiments, a system includes a server rack and an airflow blocker. The server rack includes a first vertical support with a first aperture and a second vertical support with a second aperture. The airflow blocker includes a main body, a locking element, and an anchor element. The main body includes a front side, a back side, a longitudinal axis, a first longitudinal end, and a second longitudinal end that is opposite the first longitudinal end. The main body is configured to cover a portion of the server rack. The locking element extends through the main body in a direction that is transverse to the longitudinal axis at the first longitudinal end. The locking element is configured to engage with the first aperture in the server rack. The anchor element is located at the second longitudinal end of the main body, and the anchor element is configured to engage with the second aperture in the server rack and to slide or rotate relative to the server rack.

[C2] In some embodiments, the locking element of [C1] has an unlocked state and a locked state, the unlocked state having a width that is less than a width of the second aperture, and the locked state having a width that is greater than the width of the second aperture.

[C3] In some embodiments, the locking element of [C2] includes a shoulder that engages with the second vertical support proximate the second aperture when the locking element is in the locked state.

[C4] In some embodiments, the anchor element of any of [C1] through [C3] has a corner or curve that allows the airflow blocker to rotate relative to the first vertical support.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about”, “substantially”, or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the scope of the present disclosure, and that various changes, substitutions, and alterations may be made to embodiments disclosed herein without departing from the scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A device comprising:
a main body having a front side, a back side, a longitudinal axis, a first longitudinal end, and a second longitudinal end that is opposite the first longitudinal end, the main body configured to cover a portion of a server rack;
a locking element extending through the main body in a direction that is transverse to the longitudinal axis at the first longitudinal end, the locking element being configured to engage with a first aperture in the server rack; and
an anchor element at the second longitudinal end, the anchor element being configured to engage with a second aperture in the server rack and to slide or rotate relative to the server rack.

2. The device of claim 1, the anchor element including a projection protruding from the main body at least partially in a direction that is substantially parallel to the longitudinal axis.

3. The device of claim 2, the projection having a post with a height no more than 10 mm.

4. The device of claim 2, the projection having a foot with a length no more than 20 mm.

5. The device of claim 1, the locking element having a locked state and an unlocked state, wherein the locking element has a first width in the locked state and a second width that is less than the first width in the unlocked state.

6. The device of claim 5, the unlocked state having a width no more than 10 mm.

7. The device of claim 5, the locked state and unlocked state having a difference in width of no more than 5 mm.

8. The device of claim 1, the locking element projecting in a transverse axis that is substantially perpendicular to the longitudinal axis, and wherein the locking element comprises an arm that is elastically movable.

9. The device of claim 1, the locking element including an elastically deformable clip and a plunger.

10. The device of claim 9, the elastically deformable clip having an arm that is movable in a direction that is substantially perpendicular to an insertion direction of the plunger.

11. The device of claim 9, the elastically deformable clip including an arm, and the plunger including a tapered outer surface that contacts and applies a force to the arm.

12. The device of claim 9, the elastically deformable clip including a plurality of arms, and the plunger including a tapered outer surface that contacts and applies a force to the plurality of arms.

13. The device of claim 9, the elastically deformable clip having an arm that is movable in a transverse direction that is substantially perpendicular to the longitudinal axis.

14. The device of claim 9, the elastically deformable clip having an arm that is movable in a direction that is substantially parallel to the longitudinal axis.

15. A method, comprising:
inserting a projection of an anchor element at a first end of an airflow blocking device into a first aperture of a server rack; and
locking the airflow blocking device in position by engaging a locking element with a second aperture of the server rack, the locking element being located at a second end of the airflow blocking device that is opposite the first end, the locking element extending through a main body of the airflow blocking device.

16. The method of claim 15, the locking element including an elastically deformable clip and a plunger, wherein the locking the airflow blocking device in position including sliding the plunger through the main body such that it applies a force to an arm of the elastically deformable clip.

17. A system comprising:
a server rack including:
a first vertical support having a first aperture therein, and
a second vertical support having a second aperture therein; and
an airflow blocker including:
a main body having a front side, a back side, a longitudinal axis, a first longitudinal end, and a second longitudinal end that is opposite the first longitudinal end, the main body configured to cover a portion of a server rack;
a locking element extending through the main body in a direction that is transverse to the longitudinal axis at the first longitudinal end, the locking element being configured to engage with a first aperture in the server rack; and
an anchor element at the second longitudinal end, the anchor element being configured to engage with a second aperture in the server rack and to slide or rotate relative to the server rack.

18. The system of claim 17, the locking element having an unlocked state and a locked state, the unlocked state having a width that is less than a width of the second aperture, and the locked state having a width that is greater than the width of the second aperture.

19. The system of claim 18, the locking element including a shoulder that engages with the second vertical support proximate the second aperture when the locking element is in the locked state.

20. The system of claim 17, the anchor element having a corner or curve that allows the airflow blocker to rotate relative to the first vertical support.
